(19) United States
(12) Patent Application Publication
(10) Pub. No.: US 2026/0350278 A1
(43) Pub. Date: Nov. 5, 2026

(54) VIRTUAL BATTERY SIMULATION PLATFORM

(71) Applicant: FCA US LLC, Auburn Hills, MI (US)

(72) Inventors: Gaurav Kumar, Windsor (CA); Mohamed Moalin, Windsor (CA); Mark Christie, Auburn Hills, MI (US)

(21) Appl. No.: 19/195,172

(22) Filed: Apr. 30, 2025

(51) Int. Cl. G06F 30/30

(52) U.S. Cl. CPC G06F 30/30

(57) ABSTRACT

A virtual battery simulation (VBS) platform for electrified vehicle (EV) high voltage (HV) battery testing includes a VBS computing device having a simulation environment to replicate real-time behavior of a simulated EV battery. A communication infrastructure is configured to connect to external EV battery testing equipment to enable real-time exchange of diagnostic data, control commands, and telemetry between the VBS computing device and the external EV battery testing equipment. The VBS computing device is programmed to (i) replicate electrochemical and thermal dynamics of the simulated EV battery under various environmental and operational conditions based on input signals received from the external EV battery testing equipment, and (ii) output signals of real-time EV battery behavior.

### FIELD

The present application generally relates to vehicle validation systems and, more particularly, to a virtual simulation platform for real-time electrified vehicle battery testing and predictive diagnostics.

### BACKGROUND

As the automotive industry shifts rapidly toward electric mobility, the complexity and criticality of battery pack validation has grown exponentially. Battery systems are subjected to rigorous tests across electrical, thermal, and operational domains to ensure safety, reliability, and compliance. These tests are generally executed using large-scale equipment such as battery cyclers, environmental chambers, and cooling systems, all orchestrated via automation scripts executed in various platforms. However, writing and validating these scripts is a difficult task. During early development cycles, it is common for test scripts to fail, either due to incorrect logic, improper timing, or unhandled edge cases. When such scripts are run directly on physical battery packs, the consequences can be problematic—ranging from blown fuses, contactor welds, insulation failures, or thermal events. Such failures may potentially lead to increased downtime, expensive hardware damage, and delays in validation timelines.

Moreover, battery packs differ vastly in their chemistries, configurations, and supplier specifications. Preparing and calibrating each pack for test compatibility further adds to the engineering overhead. Testing teams are often forced to wait for lab availability or sacrifice hardware integrity to meet project deadlines. Accordingly, while such conventional systems and techniques work for their intended purpose, there exists an opportunity for improvement in the relevant art.

### SUMMARY

According to one example aspect of the invention, a virtual battery simulation (VBS) platform for electrified vehicle (EV) high voltage (HV) battery testing is provided. In one exemplary implementation, the VBS platform includes a VBS computing device having one or more processors and a non-transitory computer-readable storage medium, the VBS computing device including a simulation environment to replicate real-time behavior of a simulated EV battery having individual battery cells, battery modules made up of a plurality of the individual battery cells, and a battery pack made up of a plurality of the battery modules. A communication infrastructure is configured to connect to external EV battery testing equipment to enable real-time exchange of diagnostic data, control commands, and telemetry between the VBS computing device and the external EV battery testing equipment. The VBS computing device is programmed to (i) replicate electrochemical and thermal dynamics of the simulated EV battery under various environmental and operational conditions based on input signals received from the external EV battery testing equipment, and (ii) output signals of real-time EV battery behavior.

In addition to the foregoing, the described VBS platform may include one or more of the following features: wherein the received input signals include current draw, ambient temperature, and cooling control parameters, and wherein the output signals include a terminal voltage, a battery module temperature, battery cell imbalances, and an estimated state of charge (SOC); wherein the VBS computing device includes a battery thermal system model configured to predict internal temperature gradients of the simulated EV battery based on multi-dimensional lookup tables and physical modeling equations that predict internal battery temperatures and cooling system efficiency under variable ambient and load conditions; and wherein the VBS computing device includes a cycler model configured to receive current, voltage, and power input data from the external EV battery testing equipment.

In addition to the foregoing, the described VBS platform may include one or more of the following features: wherein the VBS computing device includes an EV battery model that simulates electrochemical behavior using supplier data, open circuit voltage (OCV), internal resistance, and transient capacitance; wherein the VBS computing device includes a virtual battery management system (BMS) having an extended Kalman filter (EKF) algorithm to estimate EV battery state of charge (SOC) in real time by dynamically processing voltage, current, and temperature input signals from the external EV battery testing equipment to track an internal electrochemical state of the simulated EV battery; and wherein the VBS computing device is configured to receive and incorporate real world historical battery test data into a simulated framework of the simulated EV battery to learn from aging characteristics, chemistries, and temperature dependencies of the simulated EV battery.

In addition to the foregoing, the described VBS platform may include one or more of the following features: wherein the VBS computing device includes artificial intelligence (AI) machine learning models configured to analyze previous test sessions and automation logs to predict possible script failures, logic mismatches, and hardware risks; wherein the VBS computing device includes a cloud-based interface to enable remote access to simulation dashboards and test scenario management for multi-user collaboration; and wherein the external EV battery testing equipment includes an environment chamber, a coolant conditioning unit, and a cycler, wherein the environment chamber, the coolant conditioning unit, and the cycler are configured to receive demand input signals from automated test scripts loaded to the external EV battery testing equipment.

In accordance with another example aspect of the invention, a method of virtually testing an electrified vehicle (EV) battery with a virtual battery simulation (VBS) platform is provided. In one exemplary implementation, the VBS platform includes a VBS computing device having one or more processors and a non-transitory computer-readable storage medium, the VBS computing device including a simulation environment to replicate real-time behavior of a simulated EV battery having individual battery cells, battery modules made up of a plurality of the individual battery cells, and a battery pack made up of a plurality of the battery modules.

In one exemplary implementation, the method includes loading, by the VBS computing device, one or more models configured to replicate electrochemical and thermal dynamics of the simulated EV battery; establishing, by a communication infrastructure, a connection to external EV battery testing equipment to enable real-time exchange of diagnostic data, control commands, and telemetry between the VBS computing device and the external EV battery testing equipment; replicating, by the VBS computing device and the one or more models, electrochemical and thermal dynamics of the simulated EV battery under various environmental and operational conditions based on input signals received from the external EV battery testing equipment; and outputting, by the VBS computing device and the communication infrastructure, signals of real-time EV battery behavior.

In addition to the foregoing, the described method may include one or more of the following features: wherein the received input signals include current draw, ambient temperature, and cooling control parameters, and wherein the output signals include a terminal voltage, a battery module temperature, battery cell imbalances, and an estimated state of charge (SOC); wherein the VBS computing device includes a battery thermal system model configured to predict internal temperature gradients of the simulated EV battery based on multi-dimensional lookup tables and physical modeling equations that predict internal battery temperatures and cooling system efficiency under variable ambient and load conditions; and wherein the VBS computing device includes a cycler model configured to receive current, voltage, and power input data from the external EV battery testing equipment.

In addition to the foregoing, the described method may include one or more of the following features: wherein the VBS computing device includes an EV battery model that simulates electrochemical behavior using supplier data, open circuit voltage (OCV), internal resistance, and transient capacitance; wherein the VBS computing device includes a virtual battery management system (BMS) having an extended Kalman filter (EKF) algorithm to estimate EV battery state of charge (SOC) in real time by dynamically processing voltage, current, and temperature input signals from the external EV battery testing equipment to track an internal electrochemical state of the simulated EV battery; and wherein the VBS computing device is configured to receive and incorporate real world historical battery test data into a simulated framework of the simulated EV battery to learn from aging characteristics, chemistries, and temperature dependencies of the simulated EV battery.

In addition to the foregoing, the described method may include one or more of the following features: wherein the VBS computing device includes artificial intelligence (AI) machine learning models configured to analyze previous test sessions and automation logs to predict possible script failures, logic mismatches, and hardware risks, and a cloud-based interface to enable remote access to simulation dashboards and test scenario management for multi-user collaboration; and wherein the external EV battery testing equipment includes an environment chamber, a coolant conditioning unit, and a cycler, wherein the environment chamber, the coolant conditioning unit, and the cycler are configured to receive demand input signals from automated test scripts loaded to the external EV battery testing equipment.

In addition to the foregoing, the described method may include one or more of the following features: receiving, from the external EV battery testing equipment, current, voltage, and thermal command inputs; emulating, by the VBS computing device and virtual battery and thermal models, actual EV battery behavior, based on the received current, voltage, and thermal command inputs; processing, by the VBS computing device and an extended Kalman filter (EKF)-based battery management systems (BMS), simulated battery data from the virtual battery and thermal models; determining, by the VBS computing device, state of charge (SOC) estimations based on the processed simulated battery data; calculating and simulating, by the VBS computing device and thermal models, battery thermal responses based on coolant flow and temperature inputs from the external EV battery testing equipment and simulated battery usage conditions; and sending the determined SOC estimations and the calculated and simulated battery thermal responses to the external EV battery testing equipment.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an example virtual battery simulation (VBS) platform for electrified vehicle (EV) battery validation testing according to the principles of the present application;

FIG. 2 is a schematic diagram of an example EV battery model that may be used with the VBS platform of FIG. 1, according to the principles of the present application;

FIG. 3 is a schematic diagram of an example EV battery pack model that may be used with the VBS platform of FIG. 1, according to the principles of the present application;

FIG. 4 is a schematic diagram of an example battery management system (BMS) of the model shown in FIG. 2, according to the principles of the present application; and

FIGS. 5A-5C illustrate a flow diagram of an example operation of the VBS platform of FIG. 1, according to the principles of the present application.

### DESCRIPTION

As previously discussed, electrified vehicle (EV) battery systems are subjected to rigorous testing across electrical, thermal, and operational domains to ensure safety, reliability, and compliance. These tests are generally executed using large-scale equipment such as battery cyclers, environmental chambers, and cooling systems, all orchestrated via automation scripts executed in various platforms. However, writing and validating these scripts is difficult, and test scripts often fail, which can damage components when run directly on physical battery packs. A virtual solution that mirrors the electrochemical and thermal behavior of battery packs while interfacing with real test hardware could radically transform the testing workflow, allowing scripts to be debugged and validated in a safe, flexible, and cost-effective manner.

Accordingly, described herein are platform-based virtual battery simulation systems and methods designed to replicate real world EV battery pack behavior, including cell chemistry, thermal properties, CAN communication, and integration with cooling systems, cyclers, and environmental conditioning units. The systems enable test engineers to simulate complete testing workflows virtually, including script validation, training, and fault replication. In one example, the system operates with battery pack control modules (BPCMs), CAN networks, and MATLAB® based diagnostic and analysis tools (or any suitable mathematical modeling software).

Physical testing of EV battery packs is often costly, time-consuming, and may pose risks to hardware integrity. Further, script errors, training inefficiencies, and miscommunication with BPCMs may result in delays, battery degradation, or other issues during early testing stages. Conventional testing methods rely heavily on physical hardware (EV batteries), leading to increased testing time, safety concerns, and battery wear. Thus, the present disclosure is configured to replace early-stage physical testing with a high-fidelity virtual environment that includes exact battery pack simulation, adaptive CAN communication, and testing system models. The systems described herein advantageously enable engineers to validate scripts, replicate edge cases, and train safely before engaging real battery packs, thereby resulting in reduced cost, risk, and testing cycle time. Thus, unlike conventional tools which simulate parts of the testing process, the present disclosure offers a holistic virtual testing platform integrating real cell chemistries, thermal/cycler/environmental models, and CAN-based BPCM logic. The systems uniquely focus on pre-validation, fault replication, and training workflows, thereby preserving battery health and accelerating development with minimal hardware usage.

In one example, the described system is a virtual battery simulator (VBS) configured to provide a sophisticated simulation environment capable of replicating EV battery behavior in real time with high accuracy. The system is configured to integrate with modeling platforms (e.g., MATLAB®, Simulink®, Simscape Electrical, etc.) to provide flexibility to model a wide variety of battery chemistries, form factors, and architectures. The simulation core is capable of representing electrical and thermal responses of individual battery cells and scaling them into modules and full packs, thereby emulating both micro-level dynamics and macro-level pack behavior.

The VBS is integrated with controller area network (CAN) communication infrastructure, enabling real-time exchange of diagnostic data, control commands, and telemetry with physical testing hardware. Through this interface, the VBS mimics the behavior of a real battery pack, receiving charge/discharge commands from a Battery Cycler or test bench, processing them internally through simulated battery management system (BMS) logic, and responding with expected CAN messages such as voltages, temperatures, SOC estimates, contactor states, and fault codes. This virtual pack becomes indistinguishable from a physical one as far as the testing system is concerned.

The VBS incorporates a virtual BMS that leverages an Extended Kalman Filter (EKF) algorithm to estimate the State of Charge (SOC) in real time. This EKF system dynamically processes voltage, current, and temperature inputs to track the internal electrochemical state of the battery, adapting to varying load conditions and environmental parameters. This virtual BMS also accounts for degradation over time, temperature sensitivity, and measurement noise, thereby achieving SOC predictions that closely resemble those from a physical BMS deployed in an actual EV pack.

In some implementations, the VBS also includes a thermal modeling subsystem, which is built upon detailed three-dimensional lookup tables, where thermal resistance and capacitance values vary based on coolant flow rate, inlet/outlet temperatures, and module configuration. The thermal simulator is configured to predict internal temperature gradients across the pack, allowing validation of thermal control strategies, cooling loop effectiveness, and safety responses to thermal faults.

The VBS may also integrate historical real-world battery data into its simulation framework. As actual test data is collected over time, the simulator is configured to continuously adjust its parameters, learning from aging characteristics, chemistries, and temperature dependencies. This feedback loop ensures that simulations remain not only accurate but also predictive of future states, which is critical for aging studies, warranty evaluation, and safety validation.

To further improve testing robustness, the VBS embeds machine learning models that analyze previous test sessions and automation logs to predict possible script failures, logic mismatches, or hardware risks. These artificial intelligence (AI) models flag potential timing issues, missing diagnostic steps, or hazardous current spikes, providing real-time alerts and optimization suggestions to test engineers.

Additionally, the VBS may be supported by a cloud-based interface, allowing remote access to simulation dashboards, test scenario management, and multi-user collaboration. Thus, testing teams in different geographic locations can simultaneously observe simulation runs, modify test sequences, and analyze results using real-time synchronized data streams.

In some configurations, the VBS platform is available as a portable hardware unit. This device, built around microcontroller or embedded compute boards (e.g., Raspberry Pi® or STM32®), is preloaded with the battery model, CAN configuration, and response tables. It can be physically connected to a test bench, replacing the real battery pack, and emulate pack behavior in real time. This plug-and-play hardware module enables simulation at sites where the full simulator software stack is unavailable, such as dealership service centers, prototyping labs, or embedded system test racks.

At the core of the VBS is a scalable modeling architecture in a chosen modeling platform. Each simulated cell reflects real supplier data, including Open Circuit Voltage (OCV) versus state of charge (SOC) curves, dynamic resistance, capacity, thermal limits, and fail-safe parameters. The cells are arranged into configurable modules and packs, where users can define the number of series and parallel combinations, cooling loop topologies, and busbar resistance. The simulator processes input signals such as current draw, ambient temperature, and cooling control parameters to compute the instantaneous pack behavior. The simulator produces outputs such as terminal voltage, module temperatures, cell imbalances, and estimated SOC, all of which are transmitted in real-time over a CAN interface.

CAN communication may be implemented using platform features (e.g., Vehicle Network Toolbox), which allows full control over DBC-based message formatting. The simulator is configured to support cyclic messages, event-driven signals, diagnostic responses, and wake-up sequences. The behavior of real BMS ECUs is faithfully emulated, allowing the testing infrastructure to communicate with the VBS as if it were a live battery pack.

The EKF-based SOC estimator is configured to track the internal electrochemical state by estimating the cell's voltage drops due to ohmic and diffusion resistances. This state observer corrects for sensor errors and temperature influences, updating SOC with minimal drift even in long-duration simulations.

Thermal simulation is configured to employ real-time energy balance equations, accounting for I²R losses, ambient cooling, convective heat transfer, and material-specific heat dissipation. The thermal simulation models thermal gradients not only across individual cells but also across modules, enabling safety-critical testing such as over-temperature faults, thermal runaway prevention, and coolant circuit diagnostics.

Embedded AI analytics are configured to use supervised and unsupervised models trained on large datasets of battery test logs. These models identify patterns that lead to script failures or performance bottlenecks. By recognizing early indicators of issues—such as sudden current surges, voltage droop, or delayed diagnostic responses—the simulator warns users prior to script deployment on real systems.

A cloud interface is configured to integrate data storage, real-time dashboards, team collaboration tools, and secured simulation execution environments. Engineers can run simulations directly on cloud virtual machines, access graphical outputs, upload custom test scripts, and review post-test analytics with complete traceability.

The system includes a plug-and-play hardware unit configured to run a compiled version of the battery model, preloaded with chemistries, thermal coefficients, and response templates. It operates interfaces via CAN to any compatible tester, AVL station, or development ECU. Its form factor and low power requirements make it ideal for rapid deployment in field testing or embedded environments.

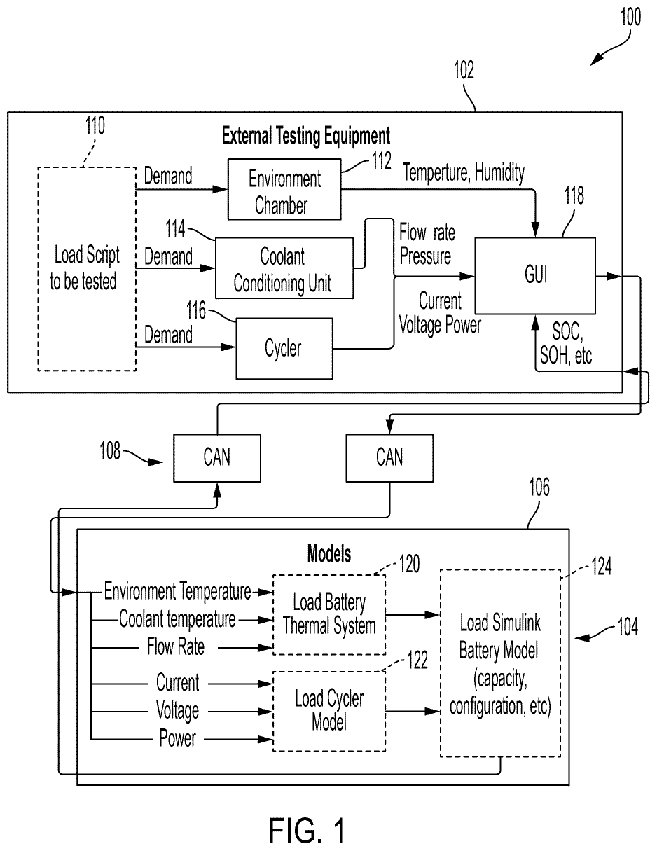

Referring now to FIG. 1, a functional block diagram of a model-based system architecture 100 for EV battery testing is illustrated according to the principles of the present application. The architecture 100, also referred to as virtual battery simulation (VBS) platform 100, generally includes external EV battery testing equipment 102 and a VBS computing device 104 configured to store/run mathematical models 106. A communication network 108, such as a CAN bus 108, is configured to provide signal communication between the testing equipment 102 and VBS computing device 104. The VBS platform 100 is a simulation environment capable of replicating EV battery behavior in real time. The mathematic models 106 provide a high-fidelity virtual representation of physical EV battery packs tailored for integration with automated testing infrastructure, such as external testing equipment 102. Thus, the VBS computing device 104 can be physically connected to the testing equipment 102, thereby replacing a real/physical battery pack and emulating battery pack behavior in real time.

In general, the mathematical models 106 provide cell-chemistry-specific battery modeling, thermal and environmental dynamics, and modular subsystem simulation. The cell-chemistry-specific battery modeling simulates electrochemical behavior using supplier data, with open circuit voltage (OCV), internal resistance, and transient capacitance, as well as temperature-dependent characteristics for accurate thermal-electric response. The thermal and environmental dynamics emulate heat generation, cooling loop interactions, and chamber conditions, thereby supporting active thermal control testing under dynamic load profiles. The modular subsystem simulation provides independent modules developed for Battery Cyclers (e.g., charge/discharge current profile emulation), Cooling Systems (e.g., coolant flow, temperature regulation logic), and Environmental Chambers (e.g., variable ambient and humidity control). Accordingly, the VBS platform 100 advantageously provides closed-loop HIL simulation for rapid script validation, safe pre-deployment testing without physical battery packs, plug-and-play compatibility with various battery platforms, and a scalable framework adaptable across cell formats and pack configurations.

With continued reference to FIG. 1, in one example, the external testing equipment 102 generally includes a script module 110, an environment chamber 112, a coolant conditioning unit 114, a cycler 116, and a graphical user interface (GUI) 118.

In the example embodiment, the script module 110 is a testing script authored within a proprietary external software platform typically utilized by battery testing facilities. The third-party script is specifically designed to manage critical hardware during testing operations, including cyclers, thermal conditioning equipment (such as coolant units), and environmental chambers. It establishes and maintains continuous communication with real battery packs, orchestrating the test execution in a smooth, safe, and efficient manner.

The battery testing scripts define a sequence of operational commands and testing profiles, such as charging and discharging currents, voltage thresholds, power limits, coolant flow rates, environmental conditions (e.g., chamber temperature and humidity), and safety interlocks that will ultimately be executed on actual battery hardware during physical validation testing.

Prior to deployment on actual battery hardware, the testing scripts must be verified for logic accuracy, functional safety, and expected system behavior. The VBS platform 100 is utilized to facilitate this verification. The VBS platform 100 provides a fully controlled, high-fidelity simulation environment capable of emulating real battery responses—including dynamic current and voltage behaviors, thermal profiles, and state-of-charge (SOC) variations—in response to scripted command sequences.

By operating within this virtual environment, engineers are able to validate, debug, and optimize testing scripts comprehensively without introducing risks to physical battery packs, expensive laboratory equipment, or system safety. For example, a testing script may instruct the cycler to apply a constant current charge of 100 A until the battery voltage reaches 400 V, transition into a constant voltage hold at 400 V until the current tapers to 10 A, while simultaneously commanding the coolant system to maintain a flow rate of 6 L/min and the environment chamber to regulate an ambient temperature of 25 °C. All such operational sequences can be fully verified within the VBS platform 100 before real-world execution, ensuring a higher level of reliability and operational integrity during physical testing.

In the example implementation, the script module 110 is configured to provide a demand input signals to the environment chamber 112, the coolant conditioning unit 114, and the cycler 116, based on the loaded script. In general, the environmental chamber 112 adjusts temperature and humidity and sends feedback to GUI 118, coolant conditioning unit 114 adjusts flow rate and pressure and sends feedback to GUI 118, and cycler 116 applies current, voltage, and power settings to the battery and sends data to GUI 118. The GUI 118 is configured to display SOC, SOH, and operational parameters for monitoring.

In the example embodiment, the environment chamber 112 is a controlled enclosure designed to simulate various ambient conditions required during battery testing. It is capable of adjusting and maintaining environmental parameters such as temperature and humidity based on commands received from the script module 110. The chamber is further configured to output real-time environmental data, such as actual temperature and humidity measurements, to the GUI 118 for monitoring and logging purposes.

The coolant conditioning unit 114 is a system configured to regulate the temperature, flow rate, and pressure of the coolant circulated to the battery thermal management system during testing. Based on the demand inputs received from the script module 110, the coolant conditioning unit adjusts its operational parameters and provides real-time feedback, including measured flow rate and pressure, to the GUI 118 for operator visibility and data recording.

The cycler 116 is a programmable load device configured to emulate charging and discharging cycles of a battery during testing. It operates by executing scripted current, voltage, and power profiles as directed by the script module 110. During operation, the cycler 116 outputs real-time electrical data—such as applied current, terminal voltage, and delivered power—which is transmitted to the graphical user interface (GUI) 118 for real-time monitoring and data logging. Although the cycler does not directly calculate state-of-charge (SOC) or state-of-health (SOH), its operation induces changes in the battery's SOC and SOH, which are independently calculated within the battery management system (BMS) and monitored through the GUI 118 alongside the cycler's real-time electrical outputs.

The GUI 118 receives various data from the environment chamber 112, the coolant conditioning unit 114, and the cycler 116, and subsequently provides the data to the mathematical models 106 via CAN 108. Additionally, the GUI 118 receives data (e.g., SOC, SOH, etc.) from the mathematical models 106 via CAN 108.

In the example embodiment, the mathematical models 106 include a battery thermal system model 120, a cycler model 122, and a battery model 124.

In general, the thermal system model 120 receives input data from the GUI 118 such as, for example, environment temperature, coolant temperature, and coolant flow rate. The thermal system model 120 outputs data to the battery model 124.

In one example, the thermal system model 120 is based on the testing script, which establishes a detailed technical framework for simulating thermal and electrochemical behavior within segmented battery packs. Each battery segment consists of grouped battery cells, modeled individually to precisely calculate thermal dynamics and cell interactions. The script methodically performs calculations essential for accurate and customizable thermal analyses, transforming input data such as cell geometry, thermal properties, and operating conditions into detailed thermal and electrical predictions.

The script provides multiple technical methods for thermal management, selectable according to specific simulation requirements:

Passive Thermal Management (Natural Convection): In the absence of active cooling systems, the script calculates heat dissipation through natural convection to the ambient environment. It defines convective heat transfer elements linked to ambient thermal nodes, converting input thermal characteristics into predicted heat losses.

Active Thermal Management via Lumped Thermal Ports: For streamlined active cooling scenarios, the script calculates conductive heat transfer via lumped thermal ports strategically positioned on battery surfaces (bottom, top, left, right, positive end, negative end). It converts input dimensions, thermal conductivity, and material characteristics into reliable thermal behavior predictions.

Advanced Active Cooling via Lookup Tables (LUT): For precise thermal modeling, the script utilizes lookup tables (LUTs) to calculate cooling efficiency based on coolant temperature and flow rates. This method transforms operational data inputs into accurate modeling of cooling scenarios under varying conditions.

The script differentiates between rectangular (pouch) and cylindrical cell geometries, adjusting thermal calculation parameters accordingly. Input geometric properties—including surface area, thickness, and orientation—are systematically processed within the script to produce accurate representations of thermal interactions.

Additionally, the script integrates external heat load calculations to comprehensively analyze additional thermal influences. Electrical interconnections and resistive components within battery sections are explicitly defined and calculated, transforming electrical parameters into precise modeling of electrical and thermal interplay across the battery assembly.

Thermal conduction between adjacent battery segments is explicitly calculated by the script, converting input thermal properties of inter-cell materials into accurate intra-pack heat flow predictions. The modular and configurable design of this script offers extensive flexibility, facilitating detailed analysis of varied battery configurations and thermal management strategies. The script's outputs significantly enhance simulation accuracy, enabling predictive analyses and reducing dependency on physical prototyping for validation.

In general, the cycler model 122 receives demand signals including target current, voltage, and power profiles from the script module 110 via the CAN communication system 108. It processes these inputs to simulate the electrical behavior of a real cycler interacting with a battery pack, generating dynamically regulated current, voltage, and power outputs that account for internal resistances, electrochemical delays, and operational constraints of the simulated battery environment. The cycler model 122 outputs data to the battery model 124.

The battery model 124 receives the regulated electrical outputs from the load cycler model 122 and the desired coolant/environment temperature, flow rate (120) to simulate the electrochemical, electrical, and thermal behavior of the battery pack. Based on the applied current, voltage, and operating conditions, the battery model 124 calculates and outputs updated battery parameters including pack voltage, pack current, State-of-Charge (SOC), State-of-Health (SOH), cell temperatures, fault conditions, etc. These outputs are transmitted back to the external testing equipment for real-time monitoring, validation, and recording during virtual testing operations.

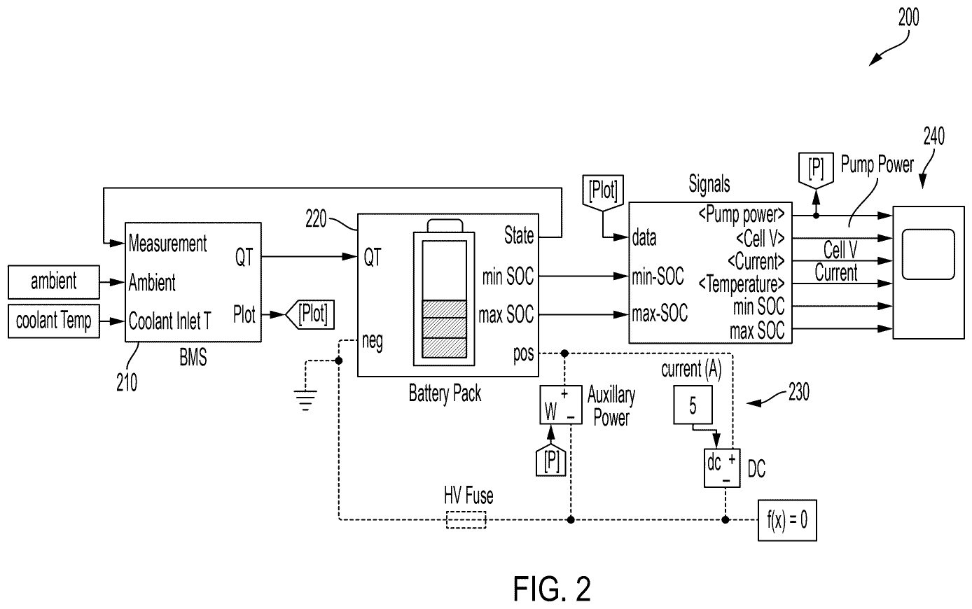

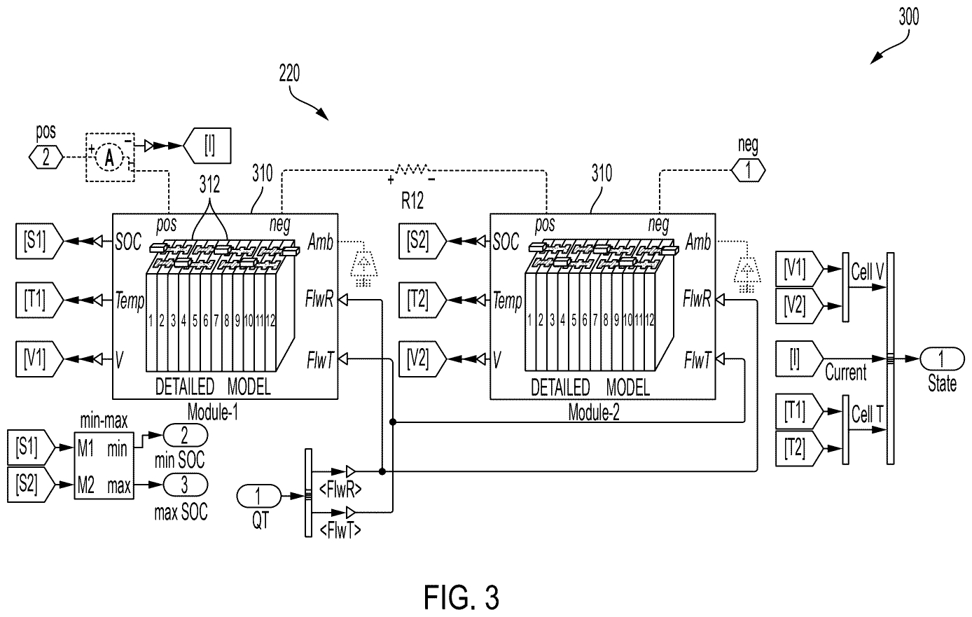

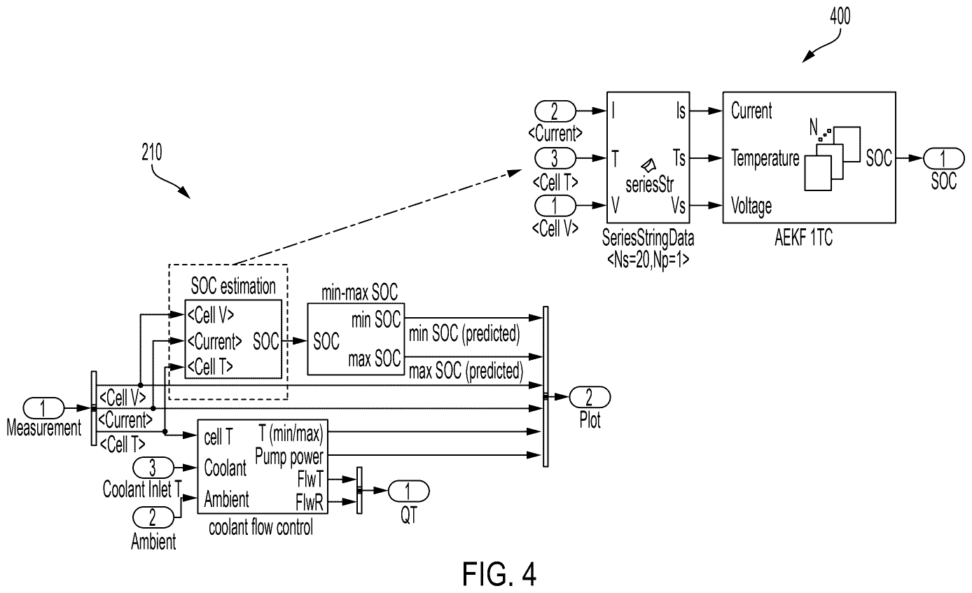

FIGS. 2-4 illustrate example portions of the battery model 124. For example, FIG. 2 illustrates an example model 200 of a battery management system (BMS) 210, battery pack 220, HV circuit 230, and pump 240. The BMS 210 receives ambient and coolant temperature inputs and monitors the SOC of the battery pack 220. The HV circuit 230 models auxiliary power paths connected to the battery. The pump 240 models a coolant pump configured to regulate coolant flow based on control signals derived from battery thermal conditions. FIG. 3 illustrates an example model 300 of the battery pack 220, which may include one or more battery modules 310 each having one or more battery cells 312. FIG. 4 illustrates an example model 400 of the BMS 210.

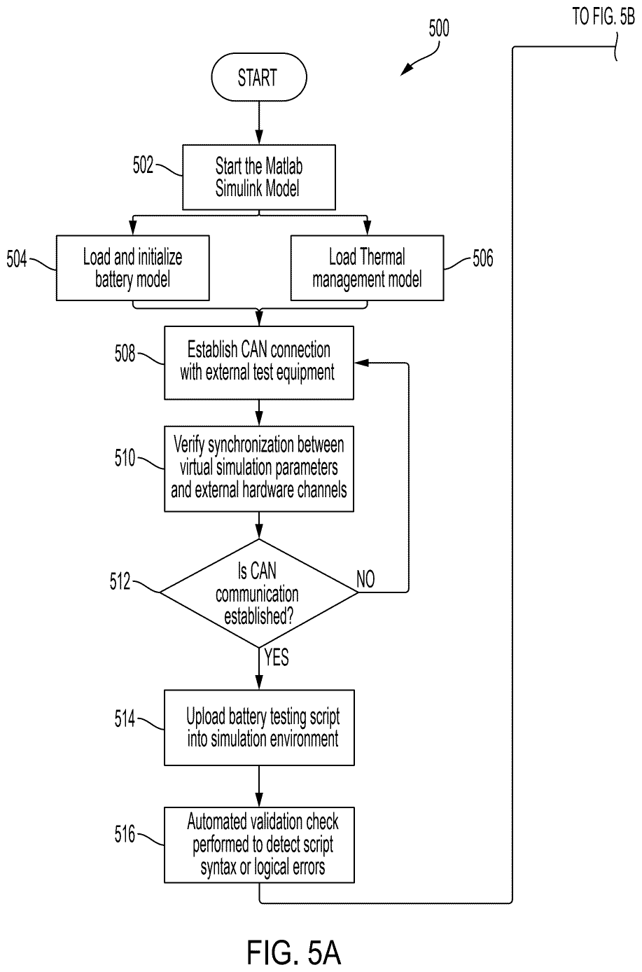

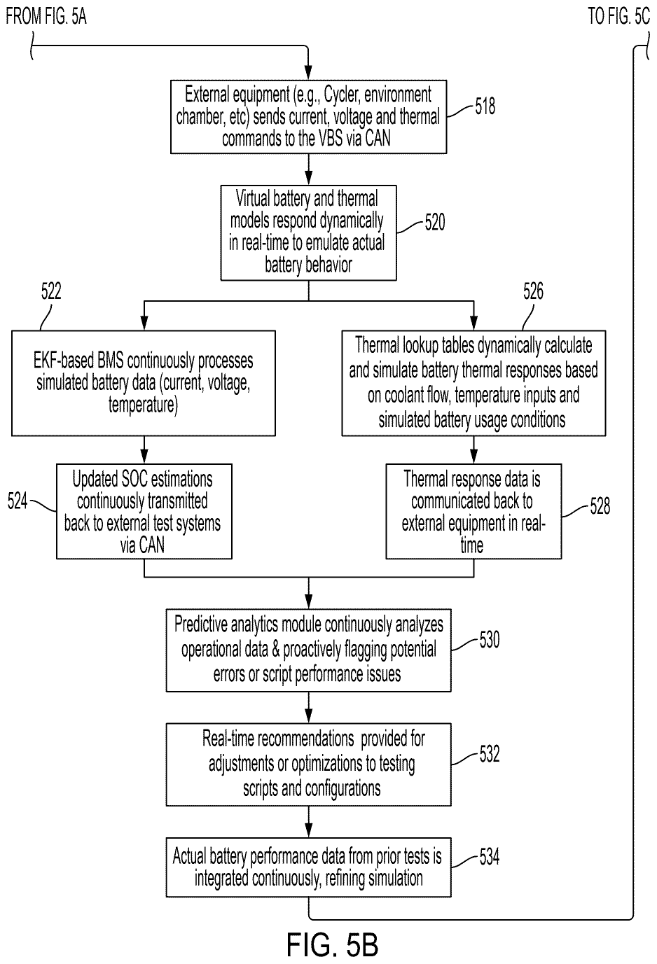

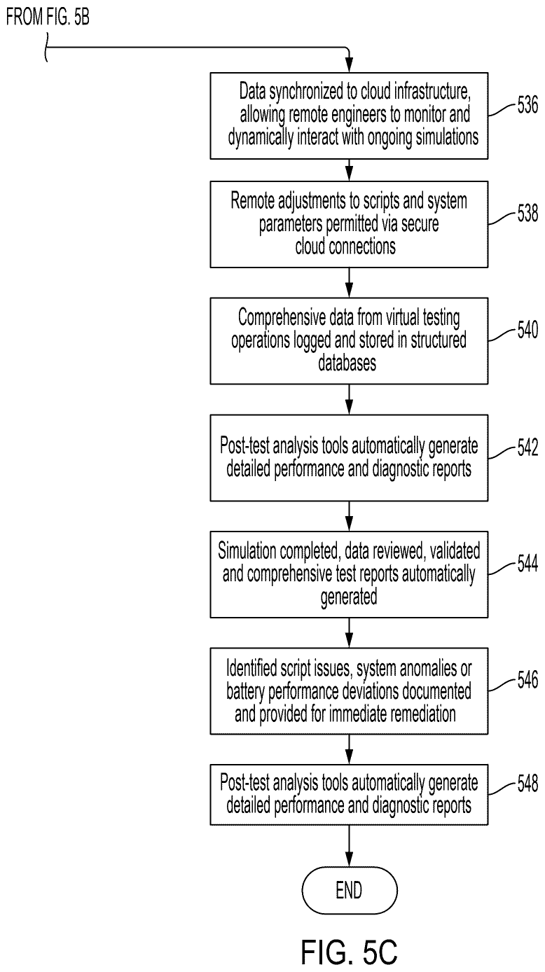

Referring now to FIGS. 5A-5C, a flow diagram of an example method 500 of operating the VBS platform 100 is illustrated according to the principles of the present application. While the method 500 specifically references the VBS platform 100, external testing equipment 102, and models 106 for illustrative/descriptive purposes, it will be appreciated that the method 500 could be applicable to any suitably configured external testing equipment and mathematical models.

In the example embodiment, the method begins at 502 where the VBS computing device 104 or other controller (“control”) launches/initiates the mathematical models 106 (e.g., program), for example, based on a user command. At 504, control loads and initializes the battery model 124, which is based on various specifications/data to represent a physical HV battery. At 506, control loads the thermal management.

At 508, control establishes signal communication with the external test equipment 102 (e.g., via CAN 108). At 510, control verifies synchronization between virtual simulation parameters and external hardware channels. At 512, control confirms if the signal communication is established with the external test equipment 102. If no, control returns to 508. If yes, control proceeds to 514 and uploads a battery testing script into the simulation environment (e.g., script module 110). At 516, control performs a validation check to detect script syntax or logical errors.

With reference now to FIG. 5B, at 518, the external test equipment 102 sends data (e.g., current, voltage, thermal commands) to the VBS mathematical models 106 (e.g., via CAN 108). At 520, the virtual battery model 124 and battery thermal system model 120 respond dynamically in real-time to emulate actual HV battery behavior. At 522, the EKF-based BMS 210 continuously processes simulated battery data (e.g., current, voltage, temperature, etc.). At 524, control continuously updates the SOC estimation and transmits back to the external testing equipment 102. Concurrently, at 526, control utilizes thermal lookup tables to dynamically calculate and simulate battery thermal responses, for example, based on coolant flow, temperature inputs, and simulated battery usage conditions. At 528, thermal response data is communicated back to the external testing equipment 102 in real-time.

At 530, control utilizes a predictive analytics module (not shown) to continuously analyze operational data and proactively flag potential errors or script performance issues. At 532, control provides real-time recommendations for adjustments or optimizations to testing scripts and configurations. At 534, control integrates actual HV battery performance data from previous tests to facilitate refining the simulation.

With reference now to FIG. 5C, at 536, control synchronizes the system data to cloud infrastructure, thereby enabling remote engineers to monitor and dynamically interact with ongoing simulations. At 538, control enables/receives remote adjustments to scripts and system parameters via secure cloud connections. At 540, control logs and stores comprehensive data from the virtual testing operation in structured databases (not shown). At 542, control utilizes post-test analysis tools to automatically generate detailed performance and diagnostic reports. At 544, control completes the simulation, reviews and validates the simulation data, and generates comprehensive test reports. At 546, control identifies and documents any script issues, system anomalies, or battery performance deviations for future remediation. At 548, control utilizes post-test analysis tools to generate detailed performance and diagnostic reports. Control then ends or returns to 502 for another test/simulation.

It will be appreciated that the term “controller” or “module” or the like as used herein refers to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It will be understood that the mixing and matching of features, elements, methodologies, systems and/or functions between various examples may be expressly contemplated herein so that one skilled in the art will appreciate from the present teachings that features, elements, systems and/or functions of one example may be incorporated into another example as appropriate, unless described otherwise above. It will also be understood that the description, including disclosed examples and drawings, is merely exemplary in nature intended for purposes of illustration only and is not intended to limit the scope of the present application, its application or uses. Thus, variations that do not depart from the gist of the present application are intended to be within the scope of the present application.

What is claimed is:

1. A virtual battery simulation (VBS) platform for electrified vehicle (EV) high voltage (HV) battery testing, the VBS platform comprising:
a VBS computing device having one or more processors and a non-transitory computer-readable storage medium, the VBS computing device including a simulation environment to replicate real-time behavior of a simulated EV battery having individual battery cells, battery modules made up of a plurality of the individual battery cells, and a battery pack made up of a plurality of the battery modules; and
a communication infrastructure for connecting to external EV battery testing equipment to enable real-time exchange of diagnostic data, control commands, and telemetry between the VBS computing device and the external EV battery testing equipment,
wherein the VBS computing device is programmed to:
(i) replicate electrochemical and thermal dynamics of the simulated EV battery under various environmental and operational conditions based on input signals received from the external EV battery testing equipment; and
(ii) output signals of real-time EV battery behavior.

2. The VBS platform of claim 1, wherein the received input signals include current draw, ambient temperature, and cooling control parameters, and
wherein the output signals include a terminal voltage, a battery module temperature, battery cell imbalances, and an estimated state of charge (SOC).

3. The VBS platform of claim 1, wherein the VBS computing device includes a battery thermal system model configured to predict internal temperature gradients of the simulated EV battery based on multi-dimensional lookup tables and physical modeling equations that predict internal battery temperatures and cooling system efficiency under variable ambient and load conditions.

4. The VBS platform of claim 1, wherein the VBS computing device includes a cycler model configured to receive current, voltage, and power input data from the external EV battery testing equipment.

5. The VBS platform of claim 1, wherein the VBS computing device includes an EV battery model that simulates electrochemical behavior using supplier data, open circuit voltage (OCV), internal resistance, and transient capacitance.

6. The VBS platform of claim 1, wherein the VBS computing device includes a virtual battery management system (BMS) having an extended Kalman filter (EKF) algorithm to estimate EV battery state of charge (SOC) in real time by dynamically processing voltage, current, and temperature input signals from the external EV battery testing equipment to track an internal electrochemical state of the simulated EV battery.

7. The VBS platform of claim 1, wherein the VBS computing device is configured to receive and incorporate real world historical battery test data into a simulated framework of the simulated EV battery to learn from aging characteristics, chemistries, and temperature dependencies of the simulated EV battery.

8. The VBS platform of claim 1, wherein the VBS computing device includes artificial intelligence (AI) machine learning models configured to analyze previous test sessions and automation logs to predict possible script failures, logic mismatches, and hardware risks.

9. The VBS platform of claim 1, wherein the VBS computing device includes a cloud-based interface to enable remote access to simulation dashboards and test scenario management for multi-user collaboration.

10. The VBS platform of claim 1, wherein the external EV battery testing equipment comprises:
an environment chamber;
a coolant conditioning unit; and
a cycler,
wherein the environment chamber, the coolant conditioning unit, and the cycler are configured to receive demand input signals from automated test scripts loaded to the external EV battery testing equipment.

11. A method of virtually testing an electrified vehicle (EV) battery with a virtual battery simulation (VBS) platform comprising a VBS computing device having one or more processors and a non-transitory computer-readable storage medium, the VBS computing device including a simulation environment to replicate real-time behavior of a simulated EV battery having individual battery cells, battery modules made up of a plurality of the individual battery cells, and a battery pack made up of a plurality of the battery modules, the method comprising:
loading, by the VBS computing device, one or more models configured to replicate electrochemical and thermal dynamics of the simulated EV battery;
establishing, by a communication infrastructure, a connection to external EV battery testing equipment to enable real-time exchange of diagnostic data, control commands, and telemetry between the VBS computing device and the external EV battery testing equipment;
replicating, by the VBS computing device and the one or more models, electrochemical and thermal dynamics of the simulated EV battery under various environmental and operational conditions based on input signals received from the external EV battery testing equipment; and
outputting, by the VBS computing device and the communication infrastructure, signals of real-time EV battery behavior.

12. The method of claim 11, wherein the received input signals include current draw, ambient temperature, and cooling control parameters, and
wherein the output signals include a terminal voltage, a battery module temperature, battery cell imbalances, and an estimated state of charge (SOC).

13. The method of claim 11, wherein the VBS computing device includes a battery thermal system model configured to predict internal temperature gradients of the simulated EV battery based on multi-dimensional lookup tables and physical modeling equations that predict internal battery temperatures and cooling system efficiency under variable ambient and load conditions.

14. The method of claim 11, wherein the VBS computing device includes a cycler model configured to receive current, voltage, and power input data from the external EV battery testing equipment.

15. The method of claim 11, wherein the VBS computing device includes an EV battery model that simulates electrochemical behavior using supplier data, open circuit voltage (OCV), internal resistance, and transient capacitance.

16. The method of claim 11, wherein the VBS computing device includes a virtual battery management system (BMS) having an extended Kalman filter (EKF) algorithm to estimate EV battery state of charge (SOC) in real time by dynamically processing voltage, current, and temperature input signals from the external EV battery testing equipment to track an internal electrochemical state of the simulated EV battery.

17. The method of claim 11, wherein the VBS computing device is configured to receive and incorporate real world historical battery test data into a simulated framework of the simulated EV battery to learn from aging characteristics, chemistries, and temperature dependencies of the simulated EV battery.

18. The method of claim 11, wherein the VBS computing device includes:
artificial intelligence (AI) machine learning models configured to analyze previous test sessions and automation logs to predict possible script failures, logic mismatches, and hardware risks; and
a cloud-based interface to enable remote access to simulation dashboards and test scenario management for multi-user collaboration.

19. The method of claim 11, wherein the external EV battery testing equipment comprises:
an environment chamber;
a coolant conditioning unit; and
a cycler,
wherein the environment chamber, the coolant conditioning unit, and the cycler are configured to receive demand input signals from automated test scripts loaded to the external EV battery testing equipment.

20. The method of claim 11, further comprising:
receiving, from the external EV battery testing equipment, current, voltage, and thermal command inputs;
emulating, by the VBS computing device and virtual battery and thermal models, actual EV battery behavior, based on the received current, voltage, and thermal command inputs;
processing, by the VBS computing device and an extended Kalman filter (EKF)-based battery management systems (BMS), simulated battery data from the virtual battery and thermal models;
determining, by the VBS computing device, state of charge (SOC) estimations based on the processed simulated battery data;
calculating and simulating, by the VBS computing device and thermal models, battery thermal responses based on coolant flow and temperature inputs from the external EV battery testing equipment and simulated battery usage conditions; and
sending the determined SOC estimations and the calculated and simulated battery thermal responses to the external EV battery testing equipment.
